(19) United States
(12) Patent Application Publication
(10) Pub. No.: US 2012/0134200 A1
(43) Pub. Date: May 31, 2012

(54) Magnetic Memory Cell With Multi-Level Cell (MLC) Data Storage Capability

(75) Inventors: Antoine Khoueir, Apple Valley, MN (US); Zheng Gao, San Jose, CA (US); Song S. Xue, Edina, MN (US)

(73) Assignee: Seagate Technology LLC, Scotts Valley, CA (US)

(21) Appl. No.: 12/955,612

(22) Filed: Nov. 29, 2010

(51) Int. Cl. G11C 11/15; G11C 11/00

(52) U.S. Cl. 365/158

(57) ABSTRACT

Method and apparatus for writing data to a magnetic memory element, such as a spin-torque transfer random access memory (STRAM) memory cell. In accordance with various embodiments, a multi-level cell (MLC) magnetic memory cell stack has first and second magnetic memory elements connected to a first control line and a switching device connected to a second control line. The first memory element is connected in parallel with the second memory element, and the first and second memory elements are connected in series with the switching device. The first and second memory elements are further disposed at different non-overlapping elevations within the stack. Programming currents are passed between the first and second control lines to concurrently set the first and second magnetic memory elements to different programmed resistances.

### SUMMARY

Various embodiments of the present invention are generally directed to a method and apparatus for writing data to a magnetic memory element, such as a spin-torque transfer random access memory (STRAM) memory cell.

In accordance with various embodiments, a multi-level cell (MLC) magnetic memory cell stack has first and second magnetic memory elements connected to a first control line and a switching device connected to a second control line. The first memory element is connected in parallel with the second memory element, and the first and second memory elements are connected in series with the switching device. The first and second memory elements are provisioned at different elevations within the memory cell stack.

Programming currents are passed between the first and second control lines to concurrently set the first and second magnetic memory elements to different programmed resistances. In some embodiments, a first write current concurrently programs the first and second elements, followed by application of a second write current in an opposing second direction to switch the first element to a different programmed resistance.

These and various other features and advantages which characterize the various embodiments of the present invention can be understood in view of the following detailed discussion and the accompanying drawings.

### BRIEF DESCRIPTION OF THE DRAWINGS

FIG. 1 provides a functional block representation of a data storage device.

FIG. 2 depicts a portion of the memory module of FIG. 1.

FIG. 3A shows an exemplary construction for a selected magnetic memory element of FIG. 2 as a stack of magnetic layers.

FIG. 3B is an exploded view of the magnetic memory element stack of FIG. 3A.

FIG. 4 is a structural depiction of a memory cell configured as in FIGS. 2-3.

FIG. 5 is an alternative structural depiction to that shown in FIG. 4.

FIG. 6 is yet another alternative structural depiction to that shown in FIG. 4.

FIG. 7 is a graphical representation of resistance and current characteristics of memory cells configured in accordance with some embodiments.

FIG. 8 is a graphical representation of resistance and current characteristics of memory cells configured in accordance with other embodiments.

FIG. 9 shows a DATA WRITE TO MLC CELL routine.

### DETAILED DESCRIPTION

The present disclosure sets forth improvements in the manner in which data may be written to magnetic memory elements, such as but not limited to spin-torque transfer random access memory (STRAM) cells.

An array of solid-state magnetic memory cells can be used to provide non-volatile storage of data bits. Some magnetic memory cell configurations include a programmable resistive element, such as a magnetic tunneling junction (MTJ). An MTJ includes a pinned reference layer having a fixed magnetic orientation in a selected direction. A free layer is separated from the reference layer by a tunneling barrier, with the free layer having a selectively variable magnetic orientation. The orientation of the free layer relative to the fixed layer establishes an overall electrical resistance of the cell, which can be detected during a read sense operation.

While magnetic memory elements have been found to efficiently store data in a compact semiconductor array environment, one issue related to such elements is the general inability to write multiple bits to magnetic memory cells using multi-level cell (MLC) programming. That is, the free layer in many magnetic memory elements can be magnetically precessed between just two magnetic states (parallel and antiparallel). This allows each magnetic memory element to store only a single bit of data using single level cell, or SLC programming.

Accordingly, various embodiments of the present invention are generally directed to an apparatus and method for carrying out MLC programming to memory cells with magnetic memory elements. As explained below, each memory cell is provisioned with two (or more) magnetic memory elements coupled in parallel with each other within the cell. Different current densities can be applied to the cell to independently switch the respective memory elements to the desired resistive states.

The use of two programmable memory elements in each cell allows the storage of two bits of data (00, 01, 10 and 11, respectively) in each cell. It will be appreciated that any plural number of memory elements can be provided in each cell. For example, the use of three memory elements would allow the storage of up to three bits of data (from 000 to 111) in each cell, and so on.

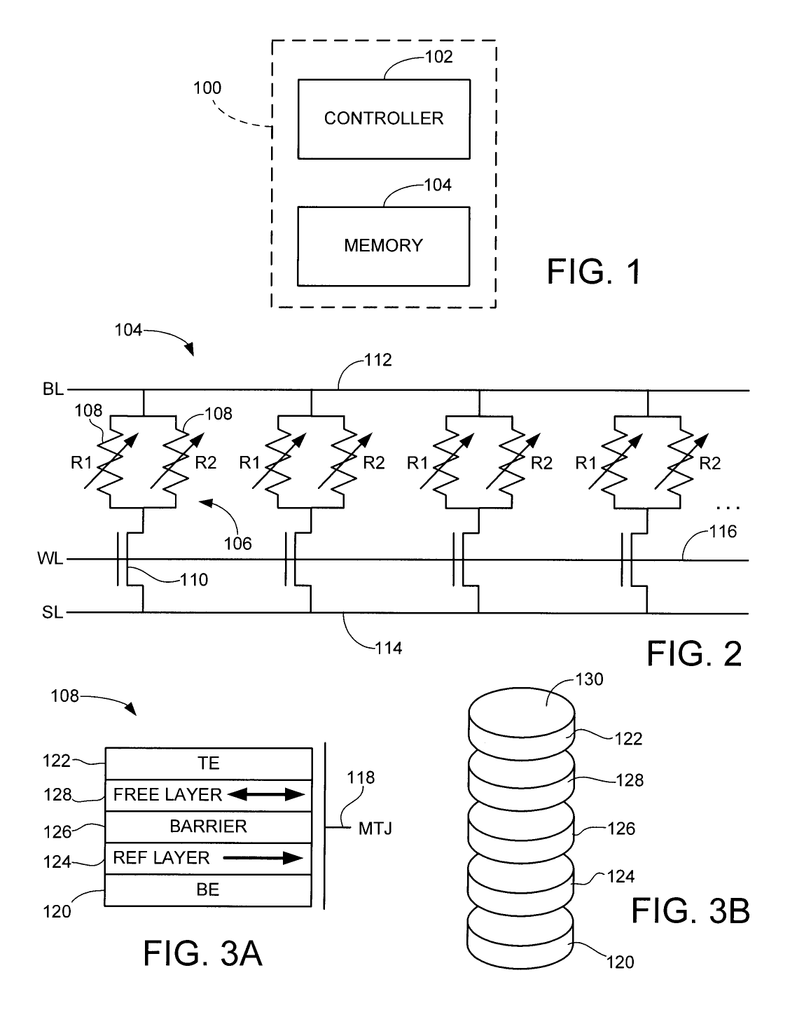

FIG. 1 provides a simplified block representation of a data storage device 100 constructed and operated in accordance with various embodiments of the present invention. It is contemplated that the device constitutes a memory card that can be mated with a portable electronic device to provide data storage for the device, although such is not limiting.

The device 100 is shown to include a controller 102 and a memory module 104. The controller 102 provides top level control of the device including interface operations with the host (not separately shown). The controller functionality may be realized in hardware or via a programmable processor, or may be incorporated directly into the memory module 104. Other features may be incorporated into the device 100 as well including but not limited to an I/O buffer, ECC circuitry and local controller cache.

The memory module 104 includes a solid-state array of non-volatile memory cells 106 as illustrated in FIG. 2. Each cell 106 includes a plurality of resistive sense memory elements 108 and a switching device 110. The memory elements 108 are represented in FIG. 2 as variable resistors, in that the elements will establish different electrical resistances responsive to programming inputs to the cells. The switching devices 110 facilitate selective access to the individual cells during read and write operations. It will be noted that the memory elements 108 in each cell 106 are connected in parallel with each other, and each memory element is further connected in series with the switching device 110.

In some embodiments, the memory cells 106 are characterized as spin-torque transfer random access memory (STRAM) cells. The memory elements 108 are characterized as magnetic tunneling junctions (MTJs), and the switching devices are characterized as nMOSFETs (n-channel metal oxide semiconductor field effect transistors). It will be appreciated that other cell configurations can readily be used including magnetic elements with giant magnetic resistance (GMR) constructions, current perpendicular to plane GMR (CPP and CCP) constructions, and other magnetic constructions that provide different resistances responsive to the application of suitable write currents thereto.

Access to the cells 106 is carried out through the use of various control lines, including bit lines (BL) 112, source lines (SL) 114 and word lines (WL) 116. All of the cells 106 along a selected word line 116 may form a page of memory that is currently accessed during read and write operations. The array may include any number of M×N memory cells arranged in rows and columns. A cross-point array can be used in which only two control lines are directly coupled to each cell.

The various bit, source and control lines 112, 114 and 116 represented in FIG. 2 extend orthogonally across the array, and may be parallel or perpendicular to each other as required. Suitable driver circuitry (not shown) is coupled to the various control lines to pass selected read and write currents through the individual cells 106.

FIG. 3A provides a vertical stack representation of a selected memory element 108 from FIG. 2. An MTJ 118 includes conductive top and bottom electrodes 120, 122 (TE and BE, respectively). A reference layer (RL) 124 has a fixed magnetic orientation in a selected direction. The reference layer 124 can take a number of forms, such as an antiferromagnetic pinned layer with the fixed magnetic orientation established by an adjacent pinning layer, such as a permanent magnet. A synthetic antiferromagnetic (SAF) structure may alternatively be used. A tunneling barrier layer 126 separates the reference layer 124 from a soft ferromagnetic free layer 128, also sometimes referred to as a storage layer.

The free layer 128 has a selectively programmable magnetic orientation that is established responsive to the application of write current to the element 108. The programmed magnetic orientation of the free layer 128 may be in the same direction as the orientation of the reference layer 124 (parallel), or may be in the opposing direction as the orientation of the reference layer 126 (antiparallel). Parallel orientation provides a lower resistance R_{L} through the memory cell, and antiparallel orientation provides a higher resistance R_{H} through the cell.

It is contemplated that the magnetization direction of the reference and free layers 124, 128 will be perpendicular to the axial direction through the cell as shown, but this is not necessarily required. For reference, the parallel orientation of the free layer provides a magnetization along an easy axis of the layer, and the antiparallel orientation of the free layer provides a magnetization along a hard axis of the layer.

While not shown in FIGS. 3A and 3B, it will be understood that the top electrode 122 establishes an electrical interconnection with the associated bit line 112 (FIG. 2), and the bottom electrode 120 establishes an electrical interconnection with the drain of the associated switching device 110.

The magnetic memory element 108 can take a variety of forms. An exemplary construction is a cylinder shape as generally depicted by an exploded representation in FIG. 3B. This provides the element 108 with a circular cross-sectional area, as shown by top surface 130 of the top electrode 122. Other cross-sectional shapes can be alternatively used, such as rectilinear. Suitable semiconductor fabrication processes can be applied to form each of the stack layers in turn.

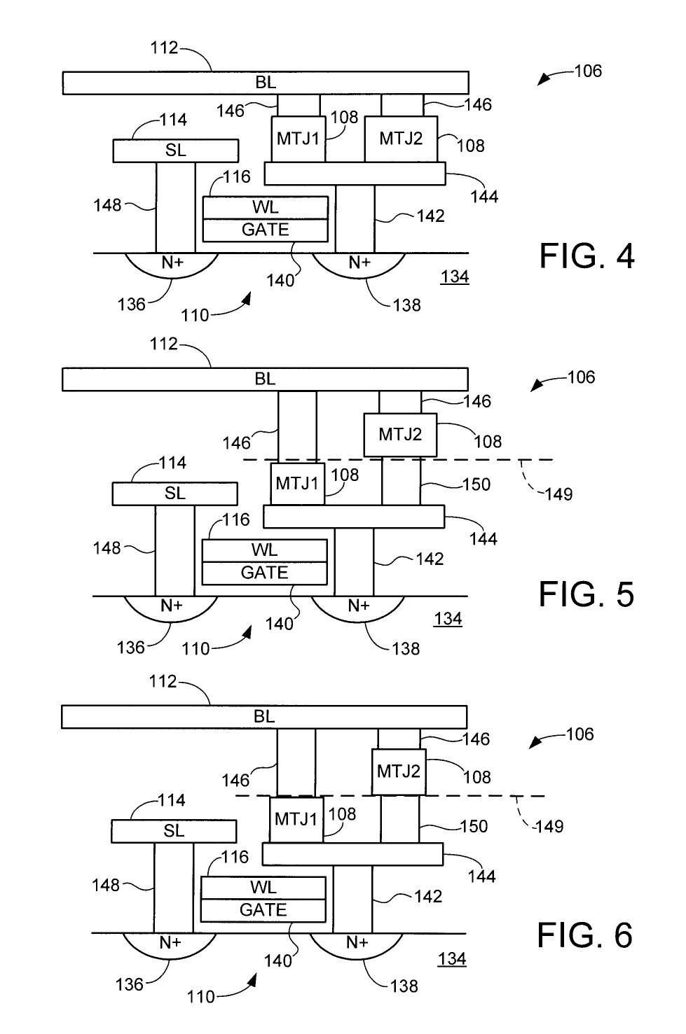

FIG. 4 shows an exemplary semiconductor configuration for the memory cells of FIGS. 2-3 in accordance with some embodiments. It will be appreciated that other cell stack configurations can be used. In FIG. 4, a base p-semiconductor substrate 134 is provided with localized N+ doped regions 136, 138. A gate structure 140 spans the regions 136, 138 to form an n-channel transistor as the switching device 110. A selected word line 116 for the cell 106 is coupled to the gate 140.

An electrically conductive structure 142 extends from the doped region 138 to support a bridging electrode 144. Two side-by-side, in-plane magnetic memory elements 108, denoted as MTJ1 and MTJ2, are supported on the electrode 144. A second extension electrode 146 extends from the MTJ1 and MTJ2 elements to contactingly engage the associated bit line 112. A third electrode structure 148 interconnects the doped region 136 with a longitudinally extending source line 114. Although not separately denoted, it will be appreciated that insulating layers of material such as silicon dioxide extend between the various elements shown in FIG. 4.

The current density required to switch the first magnetic memory element MTJ1 is selected to be different from the current density required to switch the second magnetic memory element MTJ2. The current density through the memory cell 106 is regulated by the conductivity of the MOSFET 110 which in turn is established by the voltage potential supplied to the word line 116. The magnitude and direction of current through the cell is established through the application of appropriate potentials to the bit and source lines 112, 114.

It is noted that the respective MTJ1 and MTJ2 elements lie along the same plane and can be formed concurrently during semiconductor fabrication. The different switching densities can be established by providing different sizes and/or shapes to the respective elements. For example, MTJ2 is shown to be larger in cross-sectional area than MTJ1 in FIG. 4, thereby providing MTJ2 with higher switching threshold characteristics.

FIG. 5 shows an alternative construction for the memory cells 106. The construction in FIG. 5 is generally similar to that in FIG. 4, so that like reference numerals will denote similar components. In FIG. 5, the respective magnetic elements MTJ1 and MTJ2 are aligned in non-overlapping, out-of-plane relation to one another along separate planes at different elevations within the semiconductor stack. More specifically, it is noted that MTJ1 is arranged below vertical plane line 149 and MTJ2 is above this line. During semiconductor fabrication, MTJ1 is formed first at a lower elevation within the stack and MTJ2 is formed subsequently at a higher elevation within the stack.

Providing the MTJ1 and MTJ2 memory elements 108 in different planes as shown can advantageously improve writing operations and can affect electrical resistance response because in-plane magnetic field effects from one element to the other are substantially avoided. For example, magnetic fields generated during a programming operation upon the free layer in MTJ1 may not affect the free layer in MTJ2, and vice versa, because of the differences in vertical elevation of these respective layers.

Moreover, providing the MTJ1 and MTJ2 memory elements in different, non-overlapping planes as in FIG. 5 allows the manufacturing process to be specially tuned to the manufacture of each element. A first set of processing steps can be applied to form the MTJ1 at the first, lower elevation, and then a different, second set of processing steps can be applied to form the MTJ2 at the second, higher elevation. This can increase the precision with which each of the respective types of memory elements is formed, and prevents issues relating to processing steps for one memory element adversely affecting the other element.

The amount of vertical axial separation between the respective out-of-plane MTJ1 and MTJ2 elements can vary as desired, including an out-of-plane separation that includes some amount of overlap, a lowermost portion of MTJ2 can be in the same plane as an uppermost portion of MTJ1 while the elements remain out-of-plane. In some embodiments, it may be beneficial to align the bottom electrode (BE) of MTJ2 with the top electrode (TE) of MTJ1 so that these respective elements are formed using the same metallization process. Nevertheless, these elements would remain out-of-plane for purposes herein.

An extension electrode 150 supports MTJ2 as shown to raise the MTJ2 element to the second, higher elevation. This electrode can be formed during the formation of MTJ1, and then MTJ2 can be formed subsequently on top of this electrode. As before, MTJ2 is provisioned with a different size and/or shape as compared to MTJ1, including different thicknesses of the respective internal layers, to provide different switching characteristics between the respective elements.

FIG. 6 shows the memory cell in accordance with yet further embodiments. The configuration of FIG. 6 is similar to that of FIG. 5 except that MTJ1 and MTJ2 are nominally the same size. Differences in switching characteristics are accomplished by other means, such as through the use of differently configured free layers. For example, the free layer of MTJ1 may be formed of a material that tends to precess at a different current density than the free layer of MTJ2.

The above exemplary constructions allow the memory cell 106 to take four different resistive states. The first state occurs when both of the memory elements 108 are at a lower resistance R_{L} (0,0). The second state occurs when MTJ1 is at a higher resistance R_{H} and MTJ2 remains at R_{L} (1,0). The third state occurs when MTJ1 is at the lower resistance R_{L} and MTJ2 is at R_{H} (0,1). The fourth state is when both elements are at R_{H} (1,1).

Because of the different current switching densities of the respective memory elements 108 in each cell 106, the low resistance of MTJ1, denoted as R_{H}, will be different from the low resistance of MTJ2, denoted as R_{L2}. Similarly, the high resistance of MTJ1, denoted as R_{H1}, will be different from the high resistance of MTJ2, denoted as R_{H2}. Generally, it is contemplated that R_{L2} will be greater than R_{L1} (R_{L2}>R_{L1}) and R_{H2} will be greater than R_{H1} (R_{H2}>R_{H1}).

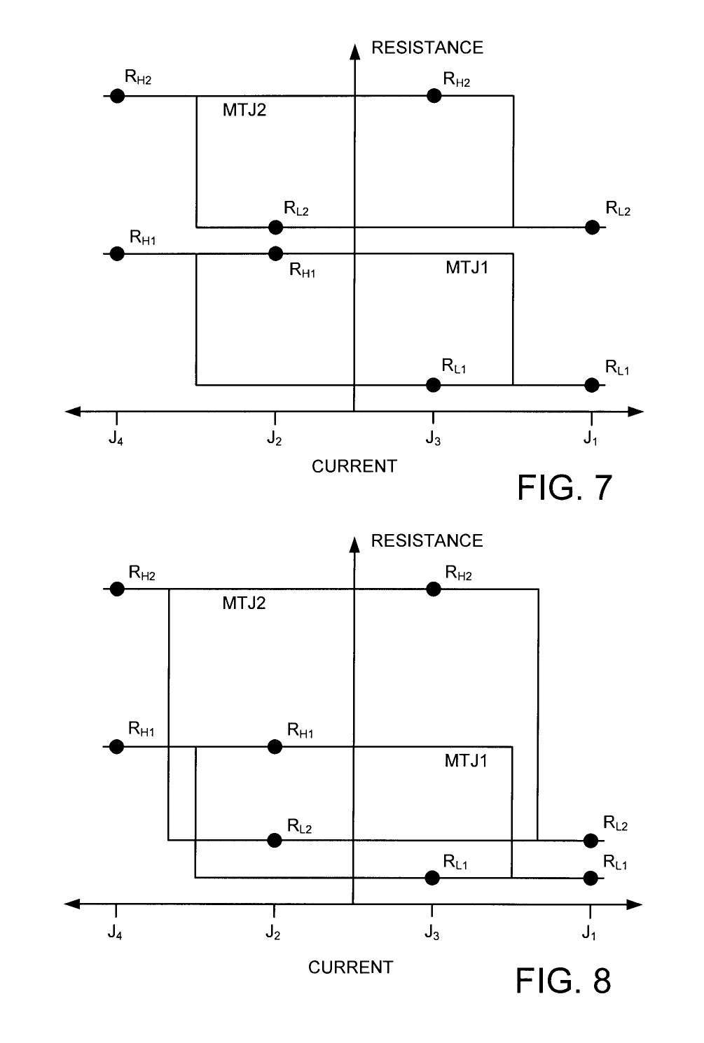

The relative values of R_{L1}, R_{L2}, R_{H1} and R_{H2} will vary depending on the construction of the respective memory elements 108. FIG. 7 shows one exemplary embodiment in which R_{H2}>R_{L2}>R_{H1}>R_{L1}. In this case, the lower resistive state R_{L2} of MTJ2 has a greater electrical resistance than the higher resistive state R_{H1} of MTJ1. This may be achieved when the memory elements MTJ1 and MTJ2 are formed on the same plane as in FIG. 4.

A current density J₁ is defined as the current density required to achieve R_{L1} for MTJ1 and R_{L2} for MTJ2. Current densities J₂, J₃ and J₄ achieve the remaining three states as shown. It will be noted that the polarity (direction of current flow) of current densities J₁ and J₃ are opposite that of current densities J₂ and J₄. In some embodiments, the (0,0) state may be achieved using a bulk refresh operation on a section of the memory array 104 by establishing a potential difference between the bit line 112 and the well of the transistor 110 to which the drain is connected.

It may be necessary in some embodiments to apply multiple successive write currents through the cell to set the MTJ1 and MTJ2 elements to the desired states. For example, to write the state (0,1) from an indeterminate initial state, it may be necessary to first apply a current with density J₄ to set the state of the cell to (1,1), followed by application of a lower current of opposite polarity with density J₃ to switch MTJ1 back to low resistance, e.g., (0,1). On the other hand, other states may be written using a single application of write current in a single direction, such as states (0,0) or (1,1). These and other operational requirements will depend on the configuration of a given cell, but can be readily incorporated by the skilled artisan in view of the present disclosure.

The MTJ1 and MTJ2 memory elements 108 operate as resistances in parallel, so that each of the above resistive states will provide a memory element resistance R(x,y) across the memory elements as follows:

$$\begin{matrix}R ( 0 , 0 ) = {R}_{L 1} + \frac{{R}_{L 2}}{( {R}_{L 1} ) ( {R}_{L 2} )} & ( 1 ) \\ R ( 1 , 0 ) = {R}_{H 1} + \frac{{R}_{L 2}}{( {R}_{H 1} ) ( {R}_{L 2} )} & ( 2 ) \\ R ( 0 , 1 ) = {R}_{L 1} + \frac{{R}_{H 2}}{( {R}_{L 1} ) ( {R}_{H 2} )} & ( 3 ) \\ R ( 1 , 1 ) = {R}_{H 1} + \frac{{R}_{H 2}}{( {R}_{H 1} ) ( {R}_{H 2} )} & ( 4 )\end{matrix}$$

Ignoring parasitic effects from the conductors and other effects, the total resistance R_{T} of the memory cell can thus be approximated as:

R_{T}=R(x,y)+R_{S} (5)

where R(x,y) is the respective memory element resistance from equations (1)-(4) and R_{S} is the drain-source resistance of the transistor 110. The programmed state of the memory cell can be sensed in any suitable manner, such as by applying a small read current through the memory cell 106 from bit line 112 to source line 114 and sensing the total voltage drop across the cell using a sense amplifier (not shown).

FIG. 8 shows an alternative graphical representation of the respective resistances of the MTJ1 and MTJ2 elements 108 where R_{H2}>R_{H1}>R_{L2}>R_{L1}. This case may be achieved with the elements being arranged on different planes, such as shown in FIG. 5. It will be noted that there is some measure of overlap between the respective minimum and maximum resistance ranges for the elements. Nevertheless, the various programmed states for the memory cell in FIG. 8 can be achieved as described above.

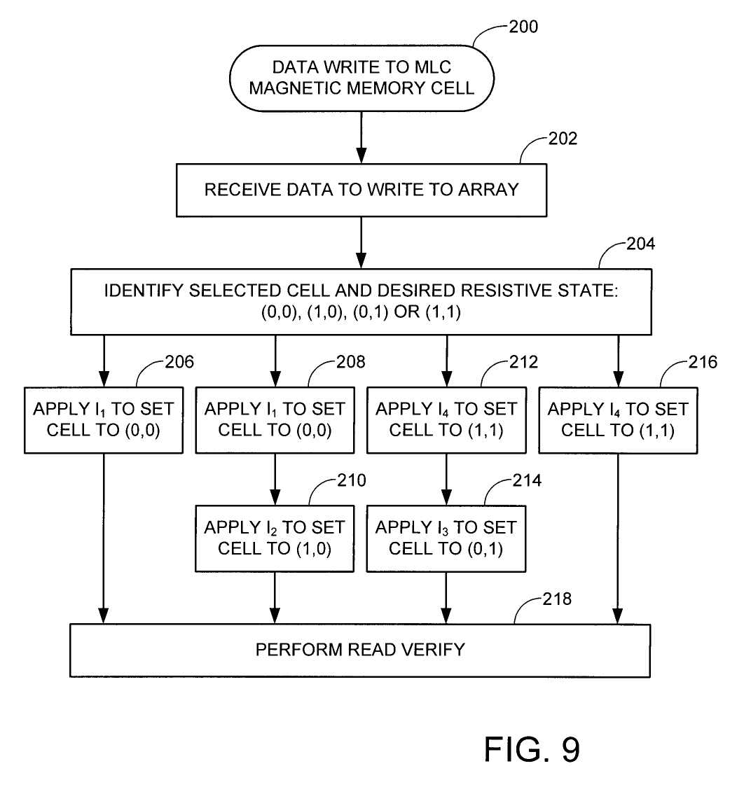

FIG. 9 shows a flow chart for a DATA WRITE TO MLC MAGNETIC MEMORY CELL routine 200, generally illustrative of steps carried out in accordance with various embodiments of the present invention.

At step 202, data to be written to the array are initially received from a host device or some other source (such as internal metadata). During this processing, one or more cells in the array 104 will be selected to receive the writeback data. The controller 102 or other control circuitry identifies the desired resistive state for each selected cell in turn, as shown by step 204. Using the above example of two-bits per cell, desired resistive state will be (0,0), (1,0), (0,1) or (1,1).

To write the selected cell to the state (0,0), the flow passes to step 206 where a relatively large current I₁ is applied through the cell having current density and polarity J₁ (see FIGS. 7-8). This will transition both MTJ1 and MTJ2 to the parallel, low resistive state (0,0).

To write the selected cell to the state (1,0), the flow passes to step 208 where the relatively large current I₁ is applied having current polarity and density J₁ to set both MTJ1 and MTJ2 to state (0,0). This is followed by step 210 where a relatively smaller current I₂ having current polarity and density J₂ is applied to switch MTJ1 to the antiparallel state. This second smaller current I₂ is insufficient to switch MTJ2 to the antiparallel state, so that the final state is (1,0).

To write the selected cell to the state (0,1), the flow passes to step 212 where a relatively large current I₄ is applied having current polarity and density J₄ to set both MTJ1 and MTJ2 to state (1,1). This is followed at step 214 with the application of a relatively smaller current I₃ with polarity and density J₃ to switch MTJ1 to the parallel state. This relatively smaller current I₃ will be insufficient to switch MTJ2 to the parallel state, resulting in the final state of (0,1).

Finally, to write the selected cell to the state (1,1), the flow passes to step 216 where the relatively large current I₄ is applied to set both MTJ1 and MTJ2 to the antiparallel state (1,1).

As desired, a read verify operation can be carried out at step 218 to validate the correct memory state was achieved, after which the process ends. It will be appreciated that the above steps 204-218 are carried out for each MLC cell to be written in turn.

The various embodiments disclosed herein are suitable for use in a write-once or write many memory. While STRAM memory cells have been used as an illustrative embodiment, the present disclosure is not so limited, as any number of different types of magnetic element constructions can incorporate the above techniques.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. An apparatus comprising a multi-level cell (MLC) magnetic memory cell stack having first and second magnetic memory elements connected to a first control line and a switching device connected to a second control line, the first memory element connected in parallel with the second memory element, the first and second memory elements each further connected in series with the switching device between the first and second control lines and disposed at respective out-of-plane axial elevations within the stack, wherein programming currents are passed between the first and second control lines to concurrently set the first and second magnetic memory elements to different programmed resistances.

2. The apparatus of claim 1, in which the first magnetic memory element is precessed to a selected magnetic orientation responsive to application of a write current through the cell having a first current density, and the second magnetic memory element requires application of a write current through the cell having a higher, second current density before precessing to the selected magnetic orientation.

3. The apparatus of claim 1, in which each of the first and second magnetic memory elements are characterized as magnetic tunneling junctions (MTJs) each having a reference layer with a fixed magnetic orientation, a free layer having a selectively programmable magnetic orientation responsive to application of a write current to the memory element and a tunnel barrier between the reference layer and the free layer.

4. The apparatus of claim 3, in which the free layers of the first and second magnetic memory elements precess to a selected programmable magnetic orientation responsive to different switching current densities.

5. The apparatus of claim 1, in which the first memory element has a first overall cross-sectional area to provide a first switching current density, and the second memory element has a different, second overall cross-sectional area to provide a different, second switching current density.

6. The apparatus of claim 1, in which the first and second magnetic memory elements each store a single bit of data responsive to a programmed resistance of the associated element so that the memory cell stores at least two bits of data.

7. The apparatus of claim 1, in which each of the first and second magnetic memory elements is respectively programmable to a relatively low electrical resistance and a relatively high electrical resistance, and the memory cell stores a multi-bit value of data responsive to a combined resistance of the first and second magnetic memory elements.

8. The apparatus of claim 1, further comprising a control circuit which applies write currents through the memory cell between the first and second control lines to store data in the respective memory elements, wherein a selected programmed state of the memory cell is achieved by passing a first, relatively larger write current in a first axial direction through the cell followed by passing a second, relatively smaller write current through the cell in an opposing second axial direction through the cell.

9. The apparatus of claim 1, in which the MLC memory cell is characterized as a first MLC memory cell, and the apparatus is characterized as a data storage device comprising a controller and a non-volatile memory module, the non-volatile memory module comprising an array of MLC memory cells nominally identical to the first MLC memory cell.

10. The apparatus of claim 1, in which the first memory element is formed using a first series of processing steps to form the first memory element at a first elevation within the memory stack, and the second memory element is formed using a different, second series of processing steps to form the second memory element at a second elevation within the memory stack in non-overlapping relation to the first elevation.

11. The apparatus of claim 1, in which the first and second memory elements are characterized as out-of-plane memory elements disposed at different, non-overlapping elevations within the memory cell stack.

12. A method comprising:
providing a multi-level cell (MLC) magnetic memory cell stack having first and second magnetic memory elements disposed at respective out-of-plane axial elevations within the stack and connected to a first control line, the memory cell stack further having a switching device connected to a second control line, the first memory element connected in parallel with the second memory element, the first and second memory elements each further connected in series with the switching device between the first and second control lines;
passing a first write current in a first axial direction through the memory cell between the first and second control lines to concurrently program the first and second magnet memory elements to respective programmed resistances; and
subsequently passing a second write current in an opposing second axial direction through the memory cell between the first and second control lines to program the first magnetic memory element to a different programmed resistance.

13. The method of claim 12, in which the first magnetic memory element is precessed to a first magnetic orientation responsive to application of the first write current, and the first magnetic memory element is subsequently precessed to an opposing second magnetic orientation responsive to application of the second write current.

14. The method of claim 12, in which each of the first and second magnetic memory elements are characterized as magnetic tunneling junctions (MTJs) each having a reference layer with a fixed magnetic orientation, a free layer having a selectively programmable magnetic orientation responsive to application of a write current to the memory element and a tunnel barrier between the reference layer and the free layer.

15. The method of claim 14, in which the free layers of the first and second magnetic memory elements precess to a selected programmable magnetic orientation responsive to different switching current densities.

16. The method of claim 12, in which the first memory element has a first overall cross-sectional area to provide a first switching current density, and the second memory element has a different, second overall cross-sectional area to provide a different, second switching current density.

17. The method of claim 12, in which each of the first and second magnetic memory elements is respectively programmable to a relatively low electrical resistance and a relatively high electrical resistance, and the memory cell stores a multi-bit value of data responsive to a combined resistance of the first and second magnetic memory elements.

18. The method of claim 12, in which the MLC memory cell is characterized as a first MLC memory cell, and the apparatus is characterized as a data storage device comprising a controller and a non-volatile memory module, the non-volatile memory module comprising an array of MLC memory cells nominally identical to the first MLC memory cell.

19. The method of claim 12, in which the first memory element is formed using a first series of processing steps to form the first memory element at a first elevation within the memory stack, and the second memory element is formed using a different, second series of processing steps to form the second memory element at a second elevation within the memory stack in non-overlapping relation to the first elevation.

20. The method of claim 12, in which the first and second memory elements are characterized as out-of-plane memory elements disposed at different, non-overlapping elevations within the memory cell stack.
